(19) United States
(12) Patent Application Publication
(10) Pub. No.: US 2010/0282321 A1
(43) Pub. Date: Nov. 11, 2010

(54) Silicon microspheres and photonic sponges, production process and their applications

(76) Inventors: Roberto Fenollosa Esteve, Valencia (ES); Francisco Javier Meseguer Rico, Valencia (ES); Mikael Tymczenko, Valencia (ES)

Correspondence Address: WENDEROTH, LIND & PONACK, L.L.P., 1030 15th Street, N.W.,, Suite 400 East, Washington, DC, 20005-1503, US

(21) Appl. No.: 11/984,870

(22) Filed: Nov. 23, 2007

(30) Foreign Application Priority Data
Jun. 18, 2007 (ES) P200701681

(51) Int. Cl. C01B 33/021; B32B 5/16; H01L 31/04; H01B 1/00; H01L 31/102

(52) U.S. Cl. 136/261; 428/402; 428/331; 204/157.45; 204/164; 252/501.1; 257/461; 257/E31.055

(57) ABSTRACT

The invention describes a microsphere with diameter from 0.1 to 50 micrometers, made of a material selected from the group consisting of: silicon, doped silicon, SiₓGe₁₋ₓ wherein 0≦x≦1, and SiₓH₁₋ₓ wherein 0.5≦x≦1, that is able to work as optical microcavity with resonating Mie modes for wavelengths from 1 to 160 micrometers, and a photonic sponge based on the above mentioned microspheres, that scatter light strongly in a wide range of wavelengths, namely from 1 to 160 micrometers. The manufacturing method is based on the decomposition of gaseous precursors by heating means. These microspheres are suitable for fabricating photonic devices like, for instance, photovoltaic cells, photodiodes, lasers and sensors.

### FIELD OF THE INVENTION

The invention relates in general to the field of microstructured materials. Particularly, it relates to those fields involving photonic technological applications, like optical microcavities, photovoltaic cells, lasers and sensors.

### BACKGROUND OF THE INVENTION

The electromagnetic energy confinement in small cavities is a phenomenon with enormous potential applications. Particularly, the resonance phenomenon of light in cavities having a size that is similar to the resonance wavelength, in the visible and in the near infrared ranges, is being currently studied by researchers and microelectronics companies from all over the world. These cavities are called microcavities because of their micrometer size. They are very promising for technological applications. Microcavities are key elements for fabricating photonic devices of micrometric size like, for instance, multiplexers and de-multiplexers. They also favour non-linear optics phenomena like, for example, Raman interactions. This can be used for detecting a liquid or a gas that is near a microcavity. Another type of technological application is a micro-laser that can be fabricated by introducing an active material inside a microcavity, and a micrometric light detector.

The development of microcavities with high quality factor (Q) resonating modes, where Q has been defined as the quantity of stored energy over the quantity of lost energy per cycle, and where the volume of confinement (V) of the electromagnetic field is very small, allowed performing quantum electrodynamics experiments by using materials with well defined electronic levels like quantum dots and even mono-atomic gases. This way, the Purcell effect and the Rabi splitting could be observed.

So far, the different types of microcavities that have been manufactured can be summarized as follows: micropillars, microdiscs, photonic crystal microcavities, micropheres and microtoroids [K. J. Vahala, Nature 424, 839, 2003]. The physics in all of them is determined by the ratio Q/V. High Q values and small V values are necessary for the previous mentioned phenomena to occur. The quality factor depends on different aspects: the microcavity refractive index, the resonance mechanism, etc. Whisppering gallery modes like resonators give the highest quality factors ever achieved so far. The record value for Q, 8×10⁹ was achieved by silicon oxide microspheres [M. L. Gorodetsky, A. A. savchenkov, V. S. Ilchenko, Opt. Lett. 21, 453, 1996]. However, their diameter was relatively large (several tens of micrometers) and therefore their volume, V, was big. The reason of this fact is the low refractive index contrast between the sphere and the surrounding environment, n_sphere/n_air=1.45, and the underlying resonance mechanism. This mechanism is based on the total internal reflexion of light inside the sphere. A strategy for decreasing the sphere size and achieving a high Q consists of increasing the refractive index of the sphere. This is the case of a silicon microsphere. Here, the refractive index contrast is n_sphere/n_air=3.5 in the infrared range.

It is worthwhile mentioning some methods used so far for manufacturing silicon spheres. For example, those described in patents [U.S. Pat. No. 4,425,408, Production of single crystal semiconductors], [U.S. Pat. No. 4,637,855, Process for producing crystalline silicon spheres], [U.S. Pat. No. 5,069,740, Production of semiconductor grade silicon spheres from metallurgical grade silicon particles], [U.S. Pat. No. 6,596,395 B1, Balls of single crystal silicon and method of making the same], and [JP-2005162609, Method for producing silicon sphere and its production apparatus]. However, it seems the spheres described in all these patents look like much bigger than the spheres of the present application. Their diameter is 0.5 millimetres or even more. The technological applications of these inventions are in the field of photovoltaic cells. Millimetre size silicon spheres can capture light more effectively than planar structures because of geometric effects.

### DESCRIPTION OF THE INVENTION

### Brief Description

One aspect of the invention is a microsphere, “microsphere of the invention” from now on, with diameter from 0.1 to 50 micrometers, and preferably with diameter from 0.5 to 5 micrometers, with controlled porosity, and made of a material selected from the group consisting of: silicon, doped silicon, SiₓGe₁₋ₓ wherein 0≦x≦1, and SiₓH₁₋ₓ wherein 0.5≦x≦1, that is able to work as optical microcavity with resonating Mie modes for wavelengths from 1 to 160 micrometers.

Another aspect of the invention is a photonic sponge, “photonic sponge of the invention” from now on, that is formed by conglomerates or random distributions of many microspheres of the invention, of only one material or of different materials, resulting in sponges composed of microspheres of identical composition or composed of microspheres of different composition. Said microspheres within the sponges are forming a layer type pile onto any surface. These sponges can localize the light in very small volumes, and scatter light in a wide wavelength range from 1 to 160 micrometers, and preferably in a range from 1 to 30 micrometers.

Another aspect of the invention is the production process of the microspheres and the photonic sponge of the invention, “process of the invention” from now on. This process can be divided into the following stages (see FIG. 1):
a) Introduction of at least a microspheres precursor material in a reactor,
b) decomposition of said precursor material by heating means,
c) microspheres nucleation into the precursor material,
d) microspheres growth until reaching sizes from 0.1 to 50 micrometers and diffusion of the particles into the precursor material, and
e) microspheres precipitation or deposition onto any surface of the reactor until achieving isolated microspheres and photonic sponges.

An additional aspect of the invention is a device or a composition, comprising the spherical particles, or microspheres, of the invention.

Finally, another aspect of the invention is a method of using the microspheres and photonic sponges of the invention in the manufacturing of photonic devices like, for instance, photovoltaic cells, photodiodes, lasers and sensors.

### DETAILED DESCRIPTION

One aspect of the invention is a microsphere, microsphere of the invention from now on, with diameter from 0.1 to 50 micrometers, and preferably with diameter from 0.5 to 5 micrometers, with controlled porosity and able to work as optical microcavity with resonating Mie modes for wavelengths from approximately 1 to 160 micrometers.

The term “microsphere” is to be understood as “a particle of spherical shape with a size from 0.1 to 50 micrometers”.

More specifically one aspect of the invention refers to a particle of spherical shape with a size from 0.1 to micrometers, made of a material selected from the group consisting of: silicon, doped silicon, SiₓGe₁₋ₓ wherein 0≦x≦1, and SiₓH₁₋ₓ wherein 0.5≦x≦1.

Said silicon can be selected from the group consisting of: amorphous silicon, polycrystalline silicon, single crystal silicon, amorphous hydrogenated silicon, porous silicon and nano-crystalline silicon.

In a particular embodiment said material is doped silicon and contains dopants selected from the group consisting of magnetically sensitive dopants, electrically sensitive dopants, optically sensitive dopants and combinations thereof. In an additional particular embodiment said doped silicon is selected from the group consisting of n-type silicon wherein said electrically sensitive dopant is phosphorous or arsenic, and p-type silicon wherein said electrically sensitive dopant is boron.

In an additional particular embodiment said optically sensitive dopants have luminescence in a wavelength range located in the wavelength range of the particle resonating modes.

In a preferred embodiment said optically sensitive dopant is erbium. Said erbium can be introduced in the particle, for instance, by ion implantation.

Another aspect of the invention is a photonic sponge composed by a random distribution of at least two particles of spherical shape with a size from 0.1 to 50 micrometers and identical chemical composition, said particles made of a material selected from the group consisting of: silicon, doped silicon, SiₓGe₁₋ₓ wherein 0≦x≦1, and SiₓH₁₋ₓ wherein 0.5≦x≦1, wherein the particles composing the sponge are polydisperse in size. Said photonic sponge can sustain optical resonances in the wavelength range from 1 micrometer to 160 micrometers. Said photonic sponge can scatter light strongly in the wavelength range from 1 micrometer to 160 micrometers.

Another aspect of the invention is a photonic sponge composed by a random distribution of at least two particles of spherical shape with a size from 0.1 to 50 micrometers and different chemical composition, said particles made of a material selected from the group consisting of: silicon, doped silicon, SiₓGe₁₋ₓ wherein 0≦x≦1, and SiₓH₁₋ₓ wherein 0.5≦x≦1, wherein the particles composing the sponge are polydisperse in size. Said photonic sponge can sustain optical resonances in the wavelength range from 1 micrometer to 160 micrometers. Said photonic sponge can scatter light strongly in the wavelength range from 1 micrometer to 160 micrometers.

Another aspect of the invention is a photonic sponge composed by a random distribution of at least two particles of spherical shape with a size from 0.1 to 50 micrometers and identical chemical composition, said particles made of a material selected from the group consisting of: silicon, doped silicon, SiₓGe₁₋ₓ wherein 0≦x≦1, and wherein 0.5≦x≦1, wherein the particles composing the sponge are monodisperse in size. Said photonic sponge can sustain optical resonances in the wavelength range from 1 micrometer to 160 micrometers. Said photonic sponge can scatter light strongly in the wavelength range from 1 micrometer to 160 micrometers.

Another aspect of the invention is a photonic sponge composed by a random distribution of at least two particles of spherical shape with a size from 0.1 to 50 micrometers, wherein the particles composing the sponge have different chemical composition, and said particles made of a material selected from the group consisting of silicon, doped silicon, SiₓGe₁₋ₓ wherein 0≦x≦1, and SiₓH₁₋ₓ wherein 0.5≦x≦1, wherein the particles composing the sponge are monodisperse in size. Said photonic sponge can sustain optical resonances in the wavelength range from 1 micrometer to 160 micrometers. Said photonic sponge can scatter light strongly in the wavelength range from 1 micrometer to 160 micrometers.

According to any embodiment, the photonic sponge may have a layer shape with thickness from 1 micrometer to about 1 meter, and area from 1 square micrometer to about 1 square meter.

According to any embodiment, the photonic sponge may produce an edge in the optical transmission signal that separates two regimes of light scattering: Rayleigh and Mie.

A preferred embodiment of the invention is a microsphere like those shown in FIG. 2. They are solid, and they are poly-disperse in size with a diameter varying from 0.5 to 5 micrometers and the type of silicon is poly-crystalline. The process to obtain these microspheres is detailed in example 3. The microspheres have a spherical shape and a smooth surface as shown in the inset of FIG. 2. This makes them able to work as optical microcavities with resonant Mie modes or whispering gallery modes. Because of their size range (from 0.5 to 5 micrometers in diameter), resonances appear in the wavelength range from 1 to 30 micrometers approximately.

FIG. 3(a) shows optical transmitance measurements of a 1.885 micrometers poly-crystalline silicon microsphere (solid curve above). The figure shows also theoretical calculation (solid curve below) according to Mie theory for a sphere of this size and supposing it is made of poly-crystalline silicon. Standard values of the refractive index of Palik known in the literature were used for this calculation. The spectra are plotted against wavelength (λ) and against size parameter which is defined as π×Φ/λ, where Φ is the sphere diameter. There is a very good agreement between theory and experiment. FIG. 3(a) shows also how each deep is associated to a resonant mode of the optical microcavity. These modes are classified as aₘₙ (Transversal Magnetic), and bₘₙ (Transversal Electric), where numbers m and n can take any value from 1 to ∝, and n≦m. However, this is a theoretical range, since in practice the limit of said value is dependent on the size of the microsphere and the silicon absorption of light for wavelengths shorter than 1 μm, i.e. there are no resonances for wavelengths shorter than 1 μm. FIG. 3(b) shows the calculation of the spatial distribution of the electric field intensity for modes b₂₁ and b₃₂. The highest quality factor that has been observed is 1000, because of the limited resolution of the spectrometer. It is obvious that higher quality factor resonances could be observed by using a spectrometer with a higher resolution. Particularly, calculation shows that some of them can reach values of 1×10⁹ and confine the electromagnetic field in a volume as small as 10⁻¹² cm³ (of 1 cubic micrometer). FIG. 3(a) shows (dashed curve) a calculation of the optical transmittance that would give a silicon oxide sphere of the same size as that of the silicon sphere. It is clear that the silicon oxide sphere does not give any clear deep or resonance.

FIG. 4(a) shows the Mie resonant modes of a 1.050 μm diameter poly-crystalline silicon sphere by means of its optical transmission spectrum. X-ray diffraction measurements were performed to confirm that microspheres are actually made of poly-crystalline silicon. FIG. 5(a) shows the X-ray diagram of a photonic sponge formed by poly-crystalline silicon microspheres and the X-ray diagram of a single crystal silicon wafer for comparison. FIG. 5(b) shows more in detail the diagrams around one of the peaks. The application of the Debye-Scherrer equation gives a crystal size of about 40 nm.

Another preferred embodiment of the invention is a microsphere with similar characteristics of sphericity and surface smoothness than those of FIG. 2, but wherein the type of silicon is amorphous instead of polycrystalline. The process to obtain these microspheres is detailed in example 1. FIG. 4(b) shows the Mie resonant modes of a 4.040 μm diameter amorphous silicon sphere by means of its optical transmission spectrum.

Another preferred embodiment of the invention is a microsphere with similar characteristics of sphericity and surface smoothness than those of FIG. 2, but where the type of silicon is not poly-crystalline, but amorphous hydrogenated porous silicon, and more specifically SiₓH₁₋ₓ 0.5≦x≦1. The process to obtain these microspheres is detailed in example 2. The reason why these microspheres are considered to have such a chemical composition is based on the fact that the decomposition time used in this case for the silane-based precursors is very short. Therefore the initial nuclei of particles do not have enough time to become silicon particles and they are formed by a silane mixture. This makes them to have a lower refractive index and a red like colour, in contrast with the silicon microspheres that posses a grey-black colour like the one of the commercial bulk silicon. FIG. 4(c) shows the Mie resonant modes of a 2.363 μm diameter SiₓH₁₋ₓ 0.5≦x≦1 sphere by means of its optical transmission spectrum. A fitting procedure gave an approximate refractive index of 2.5 for these microspheres. The reason why SiₓH₁₋ₓ 0.5≦x≦1 spheres are considered to be porous, is based on the fact that their resonant peaks are not stable when they are in contact with the open air environment. FIG. 6 shows this fact for a microsphere that was in an open air atmosphere during 1 day. A blue-shift of about 100 nm was observed comparing with the initial position of the resonant peaks. Calculations showed that this long shift can not be explained in terms of formation of any oxide layer, for instance, on the surface of the microspheres. Therefore they should have a large surface that allows the surrounding environment to influence them strongly. We confirmed that this phenomenon does not occur to the other microspheres described in the present application, namely poly-crystalline silicon, and amorphous silicon microspheres.

The obtaining of porous silicon from silicon is a scientific topic that has been extensively studied. It can be achieved by electrochemical etching means or by chemical etching means [Properties of Porous Silicon, L. Canham, Institution of Engineering and Technology, 1997]. Therefore, it is obvious that porous silicon microspheres could be easily obtained from the poly-crystalline or amorphous silicon microspheres of the present invention, described herein, by using the methods already described in the literature.

The obtaining of single crystal silicon microspheres could be achieved from the above described polycrystalline or amorphous silicon microspheres by heating them to temperatures near the melting point of silicon, see for instance [U.S. Pat. No. 4,637,855, Process for producing crystalline silicon spheres].

Silicon doped microspheres, and more specifically p-doped or n-doped silicon microspheres can be obtained by simultaneously decomposing silane or di-silane gas with small amounts of a gas that contains dopant atoms. This doping gas can be phosphine (PH₃) or arsine for n-type doping and it can be borane or diborane for p-type doping. The doping process can be also achieved after the silicon microsphere manufacturing by subjecting the microspheres to a gaseous environment containing one of those doping gases. There are examples in the literature of these types of processes, [U.S. Pat. No. 5,885,869, Method for uniformly doping hemispherical grain polycrystalline silicon] and [U.S. Pat. No. 5,278,097, Method of making doped silicon spheres].

Another type of doping can be that with erbium ions, by ion implantation, for instance. This is an optically active dopant that can be introduced into the silicon matrix easily by using methods already described in the literature, see for instance [Materials Chemistry and Physics, 54, 273-279 (1998), erbium implantation in silicon: From materials properties to light emitting devices, by Priolo F. et al.].

The obtaining of SiGe alloys, (SiₓGe₁₋ₓ 0≦x≦1) can be performed by simultaneously decomposing silane or di-silane gas with GeH₄ gas or with GeCl₄ gas. There are examples in the literature of formation of this type of alloys, [U.S. Pat. No. 4,857,270, Process for manufacturing silicon-germanium alloys, by Shinji Maruya et al.].

Another preferred embodiment of the invention is silicon microspheres, and more preferably solid polycrystalline silicon microspheres, or solid amorphous silicon microspheres that are forming part of agglomerates of few units or forming part of a photonic sponge (FIG. 7). Photonic sponges and agglomerates of few microspheres are formed at the same time than isolated microspheres, but in different parts of the reactor (see examples 1, 3 and 4). As obtained, the photonic sponges have a layer shape and they are usually several tens of micrometers in thickness and several square centimetres in area. It is obvious that these dimensions can be reduced, or greatly enlarged by using reactors bigger than those of the examples. On the other hand, photonic sponges can grow onto any surface and take the shape of the surface where they are deposited on. Moreover, a piece of photonic sponge can be cut in any desired shape.

The photonic sponges of the invention can trap and localize light in a wavelength range from 1 to 160 micrometers, and preferably in a range from 1 to 30 micrometers. The volume where light is localized can be as small as that of a single sphere. This phenomenon can be explained in terms of Mie resonances and multiple scattering of light between several particles and it favours notably non-lineal optical phenomena, for instance Anderson localization of photons, where the mean free path of a photon is of the order of the distance between particles. FIG. 7 shows an image of scanning electron microscopy at low magnification of a 60 micrometers thick photonic sponge that extends several square centimetres in area. The inset corresponds to part of the sponge at higher magnification and demonstrates that spheres arrange in tree like structures.

FIG. 8 shows (thin solid curve) the optical transmittance of a 13-μm-thick sponge formed by polycrystalline silicon microspheres deposited onto a polished silicon substrate. The silicon wafer is transparent throughout the spectral region (50% of transmission is due to reflection at the silicon surface) except in the range around 16 μm, where Si—Si and Si—Hₙ phonons are IR-active (see thick solid curve); however, the sponge shows a clear transmission edge. Transmittance decreases by two orders of magnitude (from 50% to 0.5%) in the wavelength region from 20 to 10 μm. Then, it increases slightly up to 2.5% at shorter wavelengths. This behaviour can be explained in terms of the light-scattering properties of the single microspheres that make up the sponge. To test this possibility, statistical measurements of the sizes of the spheres composing the sponge were performed. The measurements demonstrated a Gaussian distribution with an average diameter (Φ_{avg}) of 1.8 μm and a standard deviation (σ) of 0.5 μm. Then, the contribution to the scattering cross-section (σ_{sca}) of all of the spheres composing the sponge according to the identified statistical distribution was calculated. The result is plotted in FIG. 8 (thin solid curve). While one sphere produced well-defined deeps in transmission [FIG. 3(a)] the scattering cross-section of the sponge resulted in a smooth curve with a well-defined edge that complemented its transmittance spectrum. Therefore, the decrease of transmission can be associated with an increase in Mie scattering. The edge in transmission corresponds to a transition zone, indicated in grey in the figure that separates two regimes where light scatters differently. The scattering process is Rayleigh type for wavelengths longer than those of the edge zone, and it is Mie type for shorter wavelengths. Having analyzed the behaviour of one sponge, the optical properties of another sponge of nearly the same thickness (9 μm) but with a different Gaussian distribution of sphere sizes (Φ^{avg}=1.5 μm and α=0.4 μm) is showed. Because of a decrease in average sphere diameter, both the edge of transmittance and the calculated scattering cross-section (dashed curves in FIG. 8) are shifted towards shorter wavelengths compared with the previous sponge.

Isolated microspheres can be obtained from agglomerates or photonic sponges by mechanical means. The isolation method can be a smooth scratch process, a mild grinding process or a process based on ultrasounds. Once isolated spheres are obtained, it is obvious that they can be further processed so as to select for instance a group of monodisperse microspheres and form a photonic sponge containing spheres of the same size. Also, a photonic sponge formed by spheres of different composition like those detailed above (Si, Er-doped Si, p-doped Si, n-doped Si, porous Si, SiₓH₁₋ₓ 0.5≦x≦1, SiₓGe₁₋ₓ 0≦x≦1) can be obtained by mixing microspheres of different composition. In these two cases, the sponge formation method can be for instance a sedimentation process of particles in a liquid, or any particle mixing process.

According to another aspect of the invention it refers to a process for obtaining a particle of spherical shape with a size from 0.1 to 50 micrometers, made of a material selected from the group consisting of: silicon, doped silicon, SiₓGe₁₋ₓ wherein 0≦x≦1, and SiₓH₁₋ₓ wherein 0.5≦x≦1, and a photonic sponge made of said particles, comprising the steps of (see FIG. 1):
a) Introduction of at least a microspheres precursor material in a reactor,
b) decomposition of said precursor material by heating means,
c) microspheres nucleation into the precursor material,
d) microspheres growth until reaching sizes from 0.1 to 50 micrometers and diffusion of the particles into the precursor material, and
e) microspheres precipitation or deposition onto any surface of the reactor until achieving isolated microspheres and photonic sponges.

According to particular embodiments said heating method consists of irradiating light to the reactor.

According to additional particular embodiments said heating method consists of producing an electric plasma discharge inside the reactor.

According to additional particular embodiments said heating method consists of introducing a heater element inside the reactor and heat a particular volume of the inside part of the reactor.

According to additional particular embodiments said heating method consists of a combination of the following methods: irradiating light to the reactor, electric plasma discharge inside the reactor, and heating of a volume part of the inside of the reactor by a heater element.

According to particular embodiments, the precursor material is a silane-based compound SiₙH₂ₙ₊₂ wherein n=1 to ∞.

According to additional particular embodiments, the precursor material is trichlorosilane (HSiCl₃).

According to additional particular embodiments, the precursor material is silicon tetrachloride (SiCl₄).

According to additional particular embodiments, the precursor material is dichlorosilane (H₂SiCl₂).

According to additional particular embodiments, the precursor material is silicon iodide (SiI₄).

According to additional particular embodiments, the precursor material is a silane-based compound SiₙH₂ₙ₊₂ wherein n=1 to ∞, and germane-based compound GeₘH₂ₘ₊₂, wherein m=1 to ∞.

According to additional particular embodiments, the precursor material is a mixture of silane-based compounds SiₙH₂ₙ₊₂ wherein n=1 to co and GeCl₄.

According to additional particular embodiments, the precursor material is a mixture of a silane-based compound SiₙH₂ₙ₊₂ wherein n=1 to ∞ and a borane-based compound selected between borane (BH₃) and di-borane (B₂H₆).

According to additional particular embodiments, the precursor material is a mixture of a silane-based compound SiₙH₂ₙ₊₂ wherein n=1 to ∞ and phosphine (PH₃).

According to additional particular embodiments, the precursor material is a mixture of silane-based compound SiₙH₂ₙ₊₂ wherein n=1 to ∞ and arsine (AsH₃).

The gas pressure of the precursor material can be from 0.1 to 15000 Torr during the reaction.

The decomposition temperature of the precursor material can be from 100° C. to 3000° C.

The decomposition time of the precursor material can be from 1 second to 10 hours.

According to a more preferred embodiment the process of production of microspheres and photonic sponges comprises the following steps (see FIG. 1):
a) Selection of a reactor (container where the chemical reaction process occurs), wherein the selection concerns the volume, the shape and the material the reactor is made of, selection of a chemically stable substrate, wherein selection concerns the volume, the shape and the material the substrate is made of,
b) selection of the position of the substrate inside the reactor during the chemical reaction process in gas phase that gives rise to microspheres and photonic sponges, selection of the heating method, and selection of the part of the reactor to be heated,
c) Introduction of at least a microspheres precursor material in a reactor,
d) decomposition by heating of the microspheres precursor material,
e) Forming of the microspheres,
f) rain like precipitation or deposition of the microspheres onto the substrate previously introduced in the reactor, or onto the walls of the reactor giving raise to isolated microspheres and to photonic sponges.

Said substrate acts exclusively as a platform where microspheres and sponges will be deposited on.

The precursor material is preferably silane and/or disilane, in gas phase. Such precursor material/s are introduced in the reactor and they are subjected to the appropriate decomposition conditions of pressure, temperature and time.

According to preferred embodiments, the stage of synthesis of the microspheres of the invention is based on the chemical decomposition in vapour phase of silicon precursor/s material/s. The formation of the microspheres involves that solid material, preferably silicon, nucleates, diffuses into the gas, and grows in the gas until reaching a spherical shape.

More preferably the process further comprises:
extraction of residual gases from the reactor, by a set up for chemical vapour deposition and
opening of the reactor and extraction of the substrate and of the microspheres and photonic sponges that are attached to the reactor and to the substrate.

The synthesis by chemical vapour deposition means that has been used for the invention is usually used in technology for epitaxial growing of different materials, and specially for epitaxial growing of silicon [Jasinski, J. M. & Gates, S. M. Silicon Chemical Vapor Deposition One Step at a Time: Fundamental Studies of Silicon Hydride Chemistry. Acc. Chem. Res. 24, 9-15 (1991)]. An expert in this field with the information described here, can vary the quantity of the gas precursors, for instance disilane (Si₂H₆) and silane (SiH₄) (see examples); as well as the volume, shape and material the reactor is made of; as well as the volume, shape and material the substrate (where the silicon spheres are deposited) is made of, the placement of this substrate in the reactor during the deposition process, and the temperature, pressure and time of decomposition of the gases in order to obtain one type or another of microsphere, or photonic sponge of the invention.

The particles obtained by the manufacturing process have a spherical shape because of surface tension forces. The synthesis, nucleation and precipitation of spherical particles of the invention remembers the synthesis of spherical particles of silicon oxide in an aqueous media containing the appropriate precursors [Stöber, W., Fink, A. & Bohn, E., Controlled Growth of Monodisperse Silica Spheres in the Micron Size Range, J. Colloid and Interface Sci. 26, 62-69 (1968)]. The spherical particles deposit one onto another forming conglomerates and photonic sponges (FIG. 7). The size of the obtained microspheres varies from 0.5 micrometers to 5 micrometers. However, this range can be extended to the range from 0.1 to 50 micrometers by modifying the parameters of the reaction.

In a third aspect of the invention, it refers to a device comprising particles of spherical shape with a size from 0.1 to 50 micrometers, made of a material selected from the group consisting of: silicon, doped silicon, SiₓGe₁₋ₓ wherein 0≦x≦1, and SiₓH₁₋ₓ wherein 0.5≦x≦1.

According to a particular embodiment said device is a device integrated in a single particle, called p-n junction particle, or a device integrated in a photonic sponge composed by random distributions of p-n junction particles, or a device integrated in a mixture of said p-n junction particles and said photonic sponge composed by random distributions of p-n junction particles.

According to a particular embodiment said device is a metal-semiconductor barrier integrated in a single particle, called metal-semiconductor barrier particle, or said device is a metal-semiconductor barrier integrated in a photonic sponge composed by random distributions of metal-semiconductor barrier particles, or said device is a metal-semiconductor barrier integrated in a mixture of said single particles and said photonic sponges.

According to an additional particular embodiment said device is a photovoltaic cell.

According to an additional particular embodiment said device is a photodiode.

According to an additional particular embodiment said device is a photodetector in the visible and infrared ranges.

According to an additional particular embodiment said device is a laser in the visible and infrared ranges.

According to an additional particular embodiment said device is a chemical or biological sensor.

Finally, another aspect of the invention is a method of using the microspheres and photonic sponges of the invention for manufacturing photonic devices like, for instance, photovoltaic cells, photodiodes, lasers and sensors.

According to this fourth aspect of the invention, it refers to a method of using a particle of spherical shape with a size from 0.1 to 50 micrometers, made of a material selected from the group consisting of: silicon, doped silicon, SiₓGe₁₋ₓ wherein 0≦x≦1, and SiₓH₁₋ₓ wherein 0.5≦x≦1, and photonic sponges, in the manufacturing of a device, said method comprising the inclusion of said particles in the material of which said device is made of, and comprising the working of said particles or photonic sponges as optical microcavity with resonating Mie modes for wavelengths from approximately 1 to 160 micrometers.

According to a particular embodiment of the method, a p-n junction integrated in a single particle, called p-n junction particle, and/or a photonic sponge composed by random distributions of p-n junction particles are obtained.

According to an additional particular embodiment of the method a metal-semiconductor barrier integrated in a single particle, called metal-semiconductor barrier particle, and/or a photonic sponge composed by random distributions of metal-semiconductor barrier particles are obtained.

According to an additional particular embodiment of the method a photovoltaic cell is obtained.

According to an additional particular embodiment of the method a photodiode is obtained.

The application to photovoltaic cells and to photodiodes is very similar because it is based on the photon detection by a p-n junction or a p-i-n junction. Micrometer size silicon spheres could allow integrating important concepts of electronics and photonics in a single device. A feasible development is a p-n junction in a single microsphere. Here, the concept of microcavity and the concept of photodiode are integrated in a single sphere. A p-n junction in a silicon sphere has already been performed, but in spheres of 1 mm in diameter [Nature Photonics, 1, 558-559 (2007), Saving silicon]. A p-n junction could also be performed in the microspheres of the invention by following a similar method. In the framework of rectifying barriers, microspheres having a metal semiconductor barrier could be easily achieved by several methods, for instance metal sputtering on microspheres [Physics of Semiconductor Devices, S. M. Sze, John Wiley and Sons, New York, 1981].

According to an additional particular embodiment of the method a photodetector in the visible and infrared ranges is obtained.

According to an additional particular embodiment of the method a laser in the visible and infrared ranges is obtained.

The obtaining of laser emission takes advantage of light resonances in microspheres. This could be performed by introducing or adsorbing infrared fluorescent substances into the silicon microspheres that act as microcavities for amplifying stimulated emission. There are many examples of the introduction of optically active materials in microstructures to achieve lasing emission in the literature, see for instance [O. Painter, R. K. Lee, A. Scherer, A. Yariv, J. D. O'Brien, P. D. Dapkus, I. Kim, Science 284, 1819, 1999].

According to an additional particular embodiment of the method a chemical or biological sensor is obtained.

Chemical or biological sensor applications are based on the following fact: silicon microspheres have resonances at different frequencies (or wavelengths). They produce deeps in the optical transmittance spectrum. Silicon microspheres can be made porous by means of controlling the processing parameters or by a later etching treatment. If a chemical or biological substance is introduced into the pores, it modifies the refractive index of the microcavity. Therefore, the resonances will change according to their position in wavelength and the substance can be detected. There are examples in the literature that use this type of phenomenon in a microcavity for fabricating sensors, see for instance [Andrea M. Armani et al., Science, 317, 783-787 (2007)].

### DESCRIPTION OF THE FIGURES

FIG. 1 shows two configurations A and B that correspond to different ways of placing the substrate wherein microspheres are deposited. The numbers correspond to 1) Tubular oven; 2) Reactor consisting of an ampoule of quartz; 3) Closing and opening key for the ampoule; 4) Gas entrance and exit mouth. It can be opened and closed by key 3; 5) Substrate for depositing the microspheres.

FIG. 2 Scanning electron microscopy image of several microspheres. The dispersion of sizes can be clearly appreciated. The inset shows a high magnification image of a 2 micrometers diameter microsphere that demonstrates its spherical quality and the smoothness of the surface.

FIG. 3 (a) Optical transmittance measurements of a 1.885 micrometers diameter poly-crystalline silicon sphere (solid curve above) and calculation by Mie theory (solid curve below) of the optical transmittance. The deeps of transmittance correspond to Mie resonances or whispering gallery modes that are indicated under each deep by labels ‘b’ and ‘a’ for transversal electric and transversal magnetic modes respectively. The labels have two indexes; the first indicates the number of electric field intensity maximums in the half sphere perimeter, and the second indicates the number of maximums in the radial direction. For comparison, the calculated transmittance of a silica microsphere having the same diameter is also plotted (dashed curve). (b) Electric field intensity distribution of modes b_{2,1} and b_{3,2}.

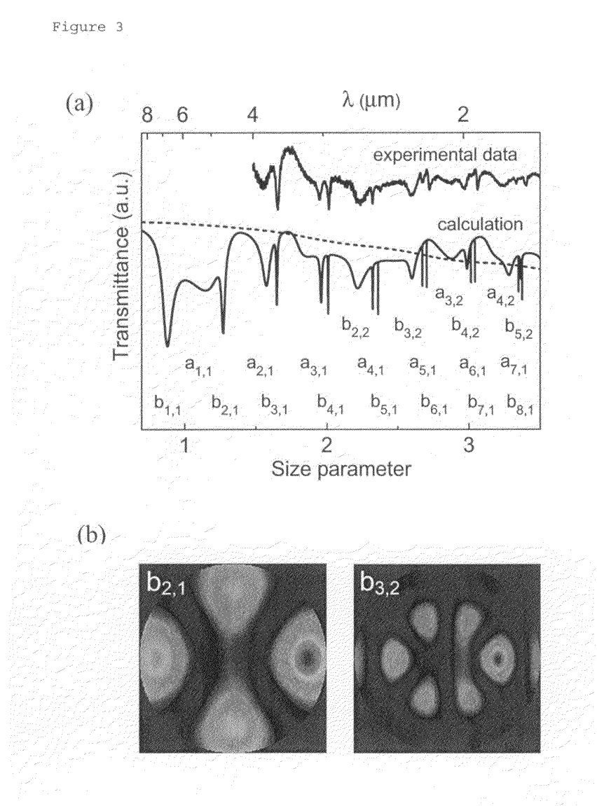

FIG. 4 Optical transmittance measurements of single spheres. (a) 1.050 μm diameter poly-crystalline silicon sphere, (b) 4.040 μm diameter amorphous silicon sphere, (c) 2.363 μm diameter SiₓH₁₋ₓ 0.5<x<1 sphere.

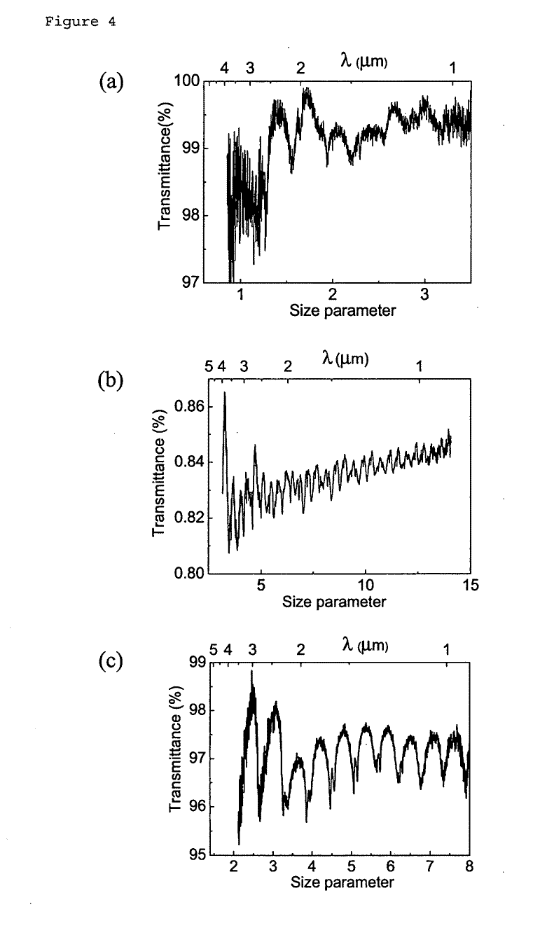

FIG. 5 X-ray diagrams of a photonic sponge formed by poly-crystalline silicon microspheres produced by decomposing di-silane gas at 800° C. during 8 hours, and of a single crystal silicon wafer for reference. (a) Diagrams in an extended range of 2φ. (b) Diagrams in a reduced range of 2φ. Debye-Scherrer equation gives a crystal size of 40 nm for the poly-crystalline silicon the spheres composing the sponge are made of.

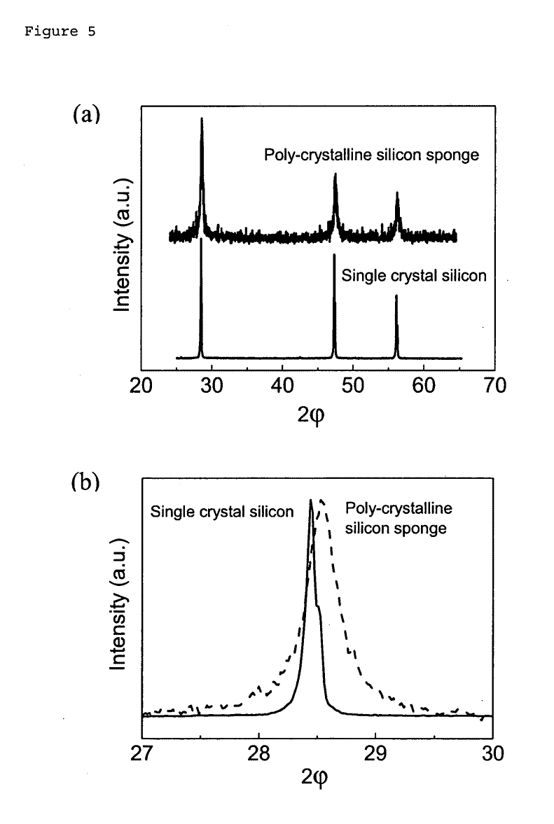

FIG. 6 Optical transmission of a 2.363 μm diameter SiₓH₁₋ₓ 0.5<x<1 sphere as grown and after 1 day of being in contact with an atmosphere of air. All the deeps show a blue shift of 100 nm.

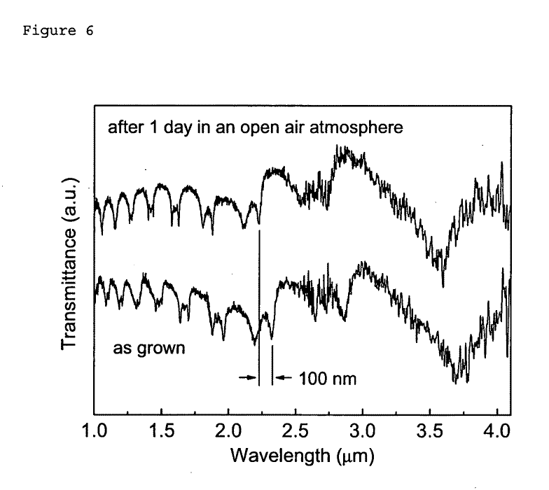

FIG. 7 Scanning electron microscopy image at low magnification of a photonic sponge. The sponge is 60 micrometers thick approximately and extends several square centimetres in area. The inset corresponds to an image of the same sponge at higher magnification.

FIG. 8 Optical properties of photonic sponges. Measured optical transmittance through a silicon substrate 0.5 mm thick (thick solid curve) and through a photonic sponge 13 μm thick that was deposited onto the silicon substrate (thin solid curve); transmittances are plotted along a wide range of wavelengths. The photonic sponge is formed by poly-crystalline silicon microspheres exhibiting a Gaussian distribution of sizes with an average diameter (Φ_{avg}) and a standard deviation (σ) of 1.8 μm and 0.5 μm, respectively. The calculated scattering cross-section (σ_{sca}) of this distribution (thin solid curve) explains the existence of a transition zone (grey area) that divides two regimes, Rayleigh and Mie, with different types of scattering. Dashed curves correspond to the transmission measurements and calculated scattering cross-section of another sponge of nearly the same thickness (9 μm) but having a different Gaussian distribution of sphere sizes (Φ_{avg}=1.5 μm and σ=0.4 μm).

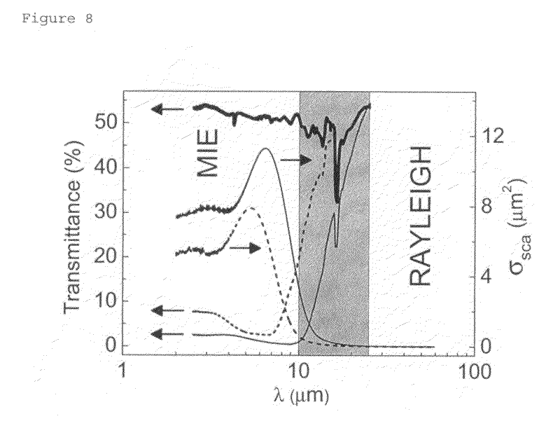

### MODES OF EMBODIMENTS OF THE INVENTION

In what follows, examples of the invention of silicon microspheres and photonic sponges are described. The dimensions of the ampoule and the oven in all of the examples are: Quartz ampoule: diameter 2 cm, length 15 cm, volume 47 ml; Tubular oven: length 20 cm, diameter 3.5 cm.

### Example 1

Synthesis of isolated amorphous silicon microspheres with diameter from 0.5 to 5 micrometers (extendable to the range from 0.1 to 50 micrometers) and a 13 micrometers thick photonic sponge that is formed by microspheres having these characteristics.

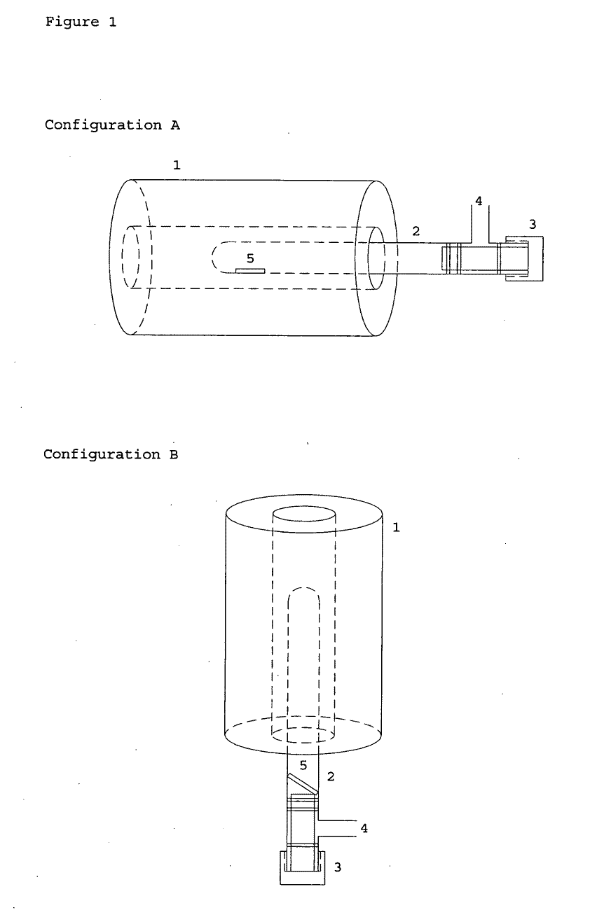

The A configuration of FIG. 1 is used in this example. The process can be summarized into the following steps:
Step 1: Key 3 is removed from the ampoule and a substrate for depositing the microspheres is introduced. The substrate is made of quartz for supporting high temperatures.
Step 2: Key 3 is put back to the ampoule, and mouth 4 is opened to a chemical vapour deposition (CVD) set up, that allows making vacuum and introducing gas inside the ampoule.
Step 3: The air of the ampoule is evacuated until reaching a pressure of 1×E−4 torr.
Step 4: Di-silane is introduced inside the ampoule by means of a liquid nitrogen trap. The quantity of introduced di-silane is 20 mg.
Step 5: Key 3 is closed and the ampoule is removed from the CVD set up. Then, the ampoule is introduced in the oven at 450° C. as shown in FIG. 1, configuration A. This way the substrate is placed in the middle point of the oven, where the temperature is stable.
Step 6: The ampoule is in the oven at 450° C. during one hour.
Step 7: The ampoule is removed from the oven and it is connected through mouth 4 to the CVD set up. Mouth 4 is opened in order to eliminate the rest of gas from the reaction, namely di-silane and hydrogen. These gases are explosive when they are in contact with air. Therefore they are trapped and deactivated in one part of the CVD set up.
Step 8: Key 3 is removed from the ampoule and the substrate containing microspheres is extracted.

The procedure of this example gives raise to a sample with the following characteristics:

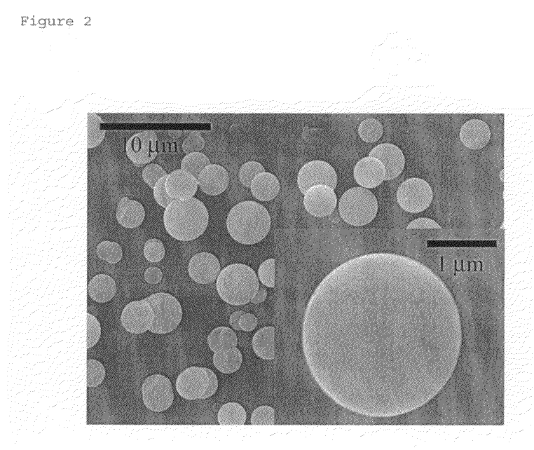

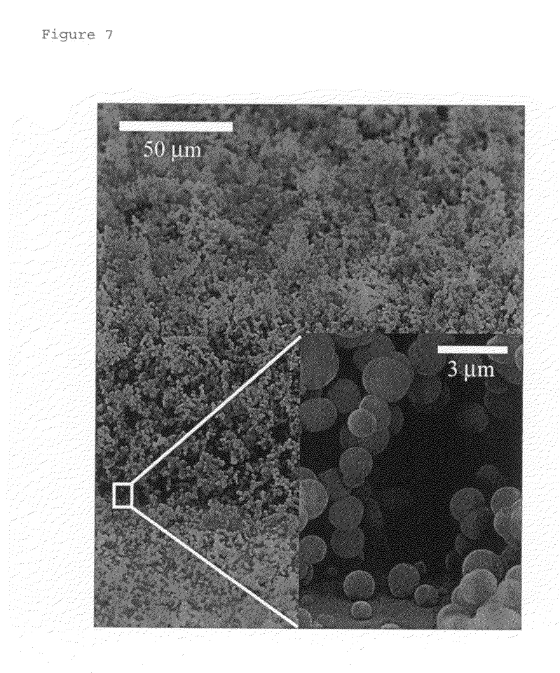

A silicon layer of about 1 micrometer in thickness has grown onto the substrate on its both faces: the face touching the ampoule walls (wall face from now on) and the opposite face (free face from now on). Isolated microspheres like those of FIG. 2 deposited onto the silicon layer of the wall face. They are made of amorphous silicon and posses a diameter from 0.5 to 5 micrometers. A photonic sponge like that of FIG. 7 deposited onto the silicon layer of the free face. This sponge is 13 micrometers thick and it is made of amorphous silicon microspheres with diameters from 0.5 to micrometers. The sponge is fragile and it can be detached from the substrate easily by using, for instance, a scalpel. If this procedure is performed, isolated microspheres like those of FIG. 2 will still remain onto the free face of the substrate. The colour of the microspheres is grey in both faces of the substrate. The range size of the microspheres can be extended to 0.1-50 micrometers by modifying the reaction parameters. Isolated microspheres can also be obtained from the photonic sponge by a mild milling, or by applying ultrasounds to the sample.

### Example 2

Synthesis of porous SiₓH₁₋ₓ 0.5<x<1 microspheres with sizes from 0.5 micrometers to 5 micrometers.

This example is similar to example 1 except in step 6, that now is:
Step 6: The ampoule is in the oven at 450° C. during 5 minutes.

The procedure of this example gives raise to a sample with the following characteristics:

A layer of SiₓH₁₋ₓ, 0.5<x<1 of less than 1 micrometer has grown onto the substrate, on both of its faces. Isolated microspheres and small agglomerates appear onto this layer in the free face. The colour of these microspheres is red and they have a diameter from 0.5 micrometers to 5 micrometers. They are made of amorphous hydrogenated silicon, more specifically SiₓH₁₋ₓ 0.5<x<1, and they are porous.

### Example 3

Synthesis of isolated poly-crystalline silicon microspheres with diameter from 0.5 to 5 micrometers (extendable to the range from 0.1 to 50 micrometers) and a 60 micrometers thick photonic sponge that is formed by microspheres having these characteristics.

This example is similar to example 1 except in step 6, that now is:
Step 6: The ampoule is in the oven at 800° C. during 1 hour.

The resulting sample is similar to the sample of example 1 except in the type of silicon the microspheres are made of. Now it is not amorphous but polycrystalline. The thickness of the sample is also different (60 micrometers). Isolated microspheres can be obtained from this sample by a mild grinding process or by using ultrasounds.

### Example 4

Synthesis of a 100 micrometers thick photonic sponge that is formed by amorphous silicon microspheres with diameter from 0.5 to 5 micrometers (extendable to the range from 0.1 to 50 micrometers).

Configuration B of FIG. 1 is used in this example. The substrate is far from the place where the ampoule is heated. The same steps as in example 1 are used here.

The obtained sample possesses the following characteristics:

The silicon layer that grew in example 1 on both faces of the substrate does not grow now because the substrate is out of the heated area. The substrate face that faces the oven shows a photonic sponge, with sphere diameter from 0.5 to 5 micrometers. The type of silicon is amorphous. The spheres grow in the heated volume and fall down onto the substrate. It is obvious that if a longer ampoule (10 meters for instance) is used, it would allow a further growing of the microspheres. This could be a way of increasing the size of the microspheres to any diameter, say 50 micrometers. On another hand the size of the microspheres could be reduced by immersing them in a silicon etching isotropic solution like HNA (hydrofluoric, nitric, acetic) acid. This way microspheres diameter could be reduced to any smaller diameter, say 0.1 micrometer.

Isolated microspheres can be obtained from this sample by a mild grinding or by using ultrasounds.

Microspheres of examples 1, 2 and 3 can be removed from the original substrate that includes the thin silicon or SiₓH₁₋ₓ, 0.5<x<1 layer that grows during the production process, and be deposited onto another substrate, for instance glass or quartz substrate. This is particularly useful for performing optical measurements whenever the influence of the thin silicon layer needs to be removed.

1. A particle of spherical shape with a size from 0.1 to 50 micrometers, made of a material selected from the group consisting of: silicon, doped silicon, SiₓGe₁₋ₓ wherein 0≦x≦1, and SiₓH₁₋ₓ wherein 0.5≦x≦1.

2. A particle according to claim 1 wherein said silicon is selected from the group consisting of: amorphous silicon, polycrystalline silicon, single crystal silicon, amorphous hydrogenated silicon, porous silicon and nano-crystalline silicon.

3. A particle according to any of claim 1 wherein said material is doped silicon and contains dopants, said dopants selected from the group consisting of magnetically sensitive dopants, electrically sensitive dopants, optically sensitive dopants and combinations thereof.

4. A particle according to claim 3 wherein said doped silicon is selected from the group consisting of n-type silicon wherein said electrically sensitive dopant is phosphorous or arsenic, and p-type silicon wherein said electrically sensitive dopant is boron.

5. A particle according to claim 3 wherein said optically sensitive dopants have luminescence in a wavelength range located in the wavelength range of the particle resonating modes.

6. A particle according to claim 3 wherein said optically sensitive dopant is erbium.

7. A photonic sponge composed by a random distribution of at least two particles defined in claim 1.

8. A photonic sponge according to claim 7, wherein the particles composing the sponge are polydisperse in size.

9. A photonic sponge according to claim 7, wherein the particles composing the sponge are monodisperse in size.

10. A photonic sponge composed by a random distribution of at least two particles, defined in claim 1, wherein the particles have identical chemical composition, being composed of a material selected from the group consisting of silicon, doped silicon, SiₓGe₁₋ₓ 0≦x≦1, and SiₓH^{1-x} 0.5≦x≦1.

11. A photonic sponge composed by a random distribution of at least two particles, defined in claim 1, wherein the particles composing the sponge have different chemical composition being composed of a material selected from the group consisting of silicon, doped silicon, SiₓGe₁₋ₓ 0≦x≦1, and SiₓH₁₋ₓ0.5≦x≦1.

12. A photonic sponge according to claim 7, wherein said photonic sponge has a layer shape with thickness from 1 micrometer to 1 meter, and area from 1 square micrometer to 1 square meter.

13. A process for obtaining a particle as claimed in claim 1, said process comprising the steps of:
a) Introduction of at least a microspheres precursor material in a reactor,
b) decomposition of said precursor material by heating means,
c) microspheres nucleation into the precursor material,
d) microspheres growth until reaching sizes from 0.1 to 50 micrometers and diffusion of the microspheres into the precursor material, and
e) microspheres precipitation or deposition onto any surface of the reactor until achieving isolated microspheres.

14. A process according to claim 13 wherein the heating method is selected from the group consisting of:
irradiating light to the reactor,
producing an electric plasma discharge inside the reactor,
introducing a heater element inside the reactor and heat a particular volume of the inside part of the reactor and
a combination of the following methods: irradiating light to the reactor, electric plasma discharge inside the reactor, and heating of a volume part of the inside of the reactor by a heater element.

15. process according to claim 13 wherein the precursor material is selected from the group consisting of:
a silane-based compound SiₙH₂ₙ₊₂ wherein n=1 to ∞
trichlorosilane (HSiCl₃)
tetrachloride (SiCl₄)
dichlorosilane (H₂SiCl₂)
silicon iodide (SiI₄).
a mixture of silane-based compound SiₙH₂ₙ₊₂ wherein n=1 to co and germane-based compound GeₘH₂ₘ₊₂, wherein m=1 to ∞
a mixture of silane-based compound SiₙH₂ₙ₊₂ wherein n=1 to ∞ and GeCl₄,
a mixture of a silane-based compound SiₙH₂ₙ₊₂ wherein n=1 to ∞ and a borane-based compound selected between borane (BH₃) and di-borane (B₂H₆),
a mixture of a silane-based compound SiₙH₂ₙ₊₂ wherein n=1 to ∞ and phosphine (PH₃), and
a mixture of a silane-based compound SiₙH₂ₙ₊₂ wherein n=1 to ∞ and arsine (AsH₃).

16. A process according to claim 13, wherein the precursor material is subjected to a gas pressure from 0.1 to 15000 Torr during the reaction.

17. A process according to claim 13, wherein the precursor material decomposes at a temperature from 100° C. to 3000° C.

18. A process according to claim 13, wherein the precursor material decomposes in a period from 1 second to 10 hours.

19. A process according to claim 13 comprising the steps:
a) selection of a reactor wherein the selection concerns the volume, the shape and the material the reactor is made of, selection of a chemically stable substrate, wherein selection concerns the volume, the shape and the material the substrate is made of,
b) selection of the position of the substrate inside the reactor during the chemical reaction process in gas phase that gives rise to microspheres and photonic sponges, selection of the heating method, and selection of the part of the reactor to be heated,
c) introduction of at least a microspheres precursor material in a reactor,
d) decomposition by heating of the microspheres precursor material,
e) forming of the microspheres,
f) rain like precipitation or deposition of the microspheres onto the substrate previously introduced in the reactor, or onto the walls of the reactor giving raise to isolated microspheres and to photonic sponges.

20. A device comprising particles of spherical shape with a size from 0.1 to 50 micrometers, made of a material selected from the group consisting of: silicon, doped silicon, SiₓGe₁₋ₓ wherein 0>x>1, and SiₓH₁₋ₓ wherein 0.5≦x≦1, photonic sponges made of said particles or a mixture of said particles and said photonic sponges.

21. A device according to claim 20, comprising a p-n junction integrated in a single particle, called p-n junction particle, a photonic sponge composed by random distributions of p-n junction particles, or a mixture of said p-n junction particles and said photonic sponge composed by random distributions of p-n junction particles.

22. A device according to claim 20 wherein said device is a metal-semiconductor barrier integrated in a single particle, called metal-semiconductor barrier particle, a photonic sponge composed by random distributions of said metal-semiconductor barrier particles, or a mixture of said metal-semiconductor barrier particles and said photonic sponge composed by random distributions of metal-semiconductor barrier particles.

23. A device according to claim 20, said device is selected from the group consisting of a photovoltaic cell, a photodiode, a photodetector in the visible and infrared ranges, a laser in the visible and infrared ranges, a chemical sensor, a biological sensor.

24. Method of using a particle as defined in claim 1 wherein said particle acts as an optical microcavity with well defined resonating Mie modes located in the wavelength range from 1 micrometer to 160 micrometers.

25. Method of using a photonic sponge as defined in claim 7, wherein said photonic sponge sustains optical resonances in the wavelength range from 1 micrometer to 160 micrometers.

26. Method of using a photonic sponge as defined in claim 7, wherein said photonic sponge scatters light strongly in the wavelength range from 1 micrometer to 160 micrometers.

27. Method of using a photonic sponge as defined in claim 7, wherein said photonic sponge produces an edge in the optical transmission signal that separates two regimes of light scattering: Rayleigh and Mie.

28. A process for obtaining a photonic sponge according to claim 7, said process comprising the steps of:
a) Introduction of at least a microspheres precursor material in a reactor,
b) decomposition of said precursor material by heating means,
c) microspheres nucleation into the precursor material,
d) microspheres growth until reaching sizes from 0.1 to 50 micrometers and diffusion of the microspheres into the precursor material, and
e) microspheres precipitation or deposition onto any surface of the reactor until achieving photonic sponges.
